(19) United States
(12) Patent Application Publication
(10) Pub. No.: US 2015/0221782 A1
(43) Pub. Date: Aug. 6, 2015

(54) VERTICAL GALLIUM NITRIDE SCHOTTKY DIODE

(71) Applicants: STMICROELECTRONICS (TOURS) SAS, Tours (FR); CENTRE NATIONAL DE LA RECHERCHE SCIENTIFIQUE, Paris Cedex (FR); UNIVERSITE FRANCOIS RABELAIS, Tours (FR)

(72) Inventors: Arnaud YVON, Saint-Cyr sur Loire (FR); Daniel ALQUIER, Tours (FR); Yvon Cordier, Les Esterets du Lac (FR)

(21) Appl. No.: 14/607,577

(22) Filed: Jan. 28, 2015

(30) Foreign Application Priority Data
Feb. 5, 2014 (FR) 1450886

(51) Int. Cl. H01L 29/872; H01L 29/20; H01L 29/66

(52) U.S. Cl. CPC H01L 29/872; H01L 29/66143; H01L 29/2003

(57) ABSTRACT

A Schottky diode may include a semiconductor substrate having first and second opposing surfaces, and a buffer layer over the first surface of the semiconductor substrate. The Schottky diode may include a first doped GaN layer over the buffer layer and having first and second opposing surfaces, the second surface of the first doped GaN layer being adjacent the buffer layer, and a second doped GaN layer over the second surface of the first doped GaN layer and having a dopant concentration level less than a dopant concentration level of the first doped GaN layer. The buffer layer, the first doped GaN layer, and the second doped GaN layer may define an opening. The Schottky diode may include a first metallization layer being coupled to the semiconductor substrate and to the first surface of the first doped GaN layer and being in the opening.

### RELATED APPLICATION

This application claims priority to French Patent application No. 14/50886, filed on Feb. 5, 2014, the contents of which are hereby incorporated by reference in their entirety.

### TECHNICAL FIELD

The present disclosure relates to a Schottky diode comprising a Schottky contact between a gallium nitride layer and a metal layer.

### BACKGROUND

There are approaches for forming Schottky diodes that use doped gallium nitride (GaN) as a semiconductor material. Gallium nitride has properties which make it particularly attractive, especially for high-power applications. Existing GaN Schottky diode structures may have various disadvantages.

### SUMMARY

Generally speaking, a Schottky diode may include a semiconductor substrate having first and second opposing surfaces, and a buffer layer over the first surface of the semiconductor substrate. The Schottky diode may include a first doped GaN layer over the buffer layer and having first and second opposing surfaces, the second surface of the first doped GaN layer being adjacent the buffer layer, and a second doped GaN layer over the second surface of the first doped GaN layer and having a dopant concentration level less than a dopant concentration level of the first doped GaN layer. The buffer layer, the first doped GaN layer, and the second doped GaN layer may define an opening. The Schottky diode may include a Schottky contact over the second doped GaN layer and spaced apart from the opening, and a first metallization layer being coupled to the semiconductor substrate and to the first surface of the first doped GaN layer and being in the opening.

### BRIEF DESCRIPTION OF THE DRAWINGS

FIG. 1 is a schematic diagram of a cross-sectional view illustrating a first embodiment of a GaN Schottky diode.

FIG. 2 is a schematic diagram of a cross-sectional view illustrating a second embodiment of a GaN Schottky diode.

FIG. 3 is a schematic diagram of a cross-sectional view illustrating a third embodiment of a GaN Schottky diode.

FIG. 4 is a schematic diagram of a cross-sectional view illustrating a fourth embodiment of a GaN Schottky diode;

FIGS. 5A to 5C are schematic diagrams of a cross-sectional view illustrating steps of an embodiment of a method of manufacturing a GaN Schottky diode.

FIGS. 6A and 6B are schematic diagrams of a cross-sectional view illustrating steps of another embodiment of a method of manufacturing a GaN Schottky diode.

### DETAILED DESCRIPTION

For clarity, the same elements have been designated with the same reference numerals in the various drawings and, further, as usual in the representation of integrated circuits, the various drawings are not to scale. Further, in the following description, terms referring to directions, such as “vertical”, “horizontal”, “lateral”, “under”, “above”, “upper”, “lower”, “topping”, “covering”, etc., apply to components arranged as illustrated in the corresponding cross-sectional views, it being understood that, in operation, the components may have different directions.

Thus, an embodiment provides a Schottky diode comprising a conductor or semiconductor substrate covered with a stack comprising: in the following order from a first surface of the substrate, a buffer layer, a first N-type doped GaN layer, and a second N-type doped GaN layer having a lower doping level than the first layer; a Schottky contact on a first surface opposite to the substrate of the second GaN layer; and a first metallization connecting to the substrate a first surface opposite to the substrate of the first GaN layer, the metallization being located in an opening located in an area of the stack which is not coated with the Schottky contact, this opening extending from the first surface of the second layer to the substrate. The diode may further comprise a second metallization coating a second surface of the substrate opposite to the first surface of the substrate. The opening may comprise a first peripheral portion crossing the second GaN layer and emerging onto the first surface of the first GaN layer, and a central portion crossing the two GaN layers and the buffer layer, and extending all the way to the substrate.

According to an embodiment, the opening stops on the first surface of the substrate. Also, the opening may continue all the way to an intermediate level of the substrate. For example, the substrate is made of silicon. In some embodiments, the first metallization is not intended to be connected to an external component.

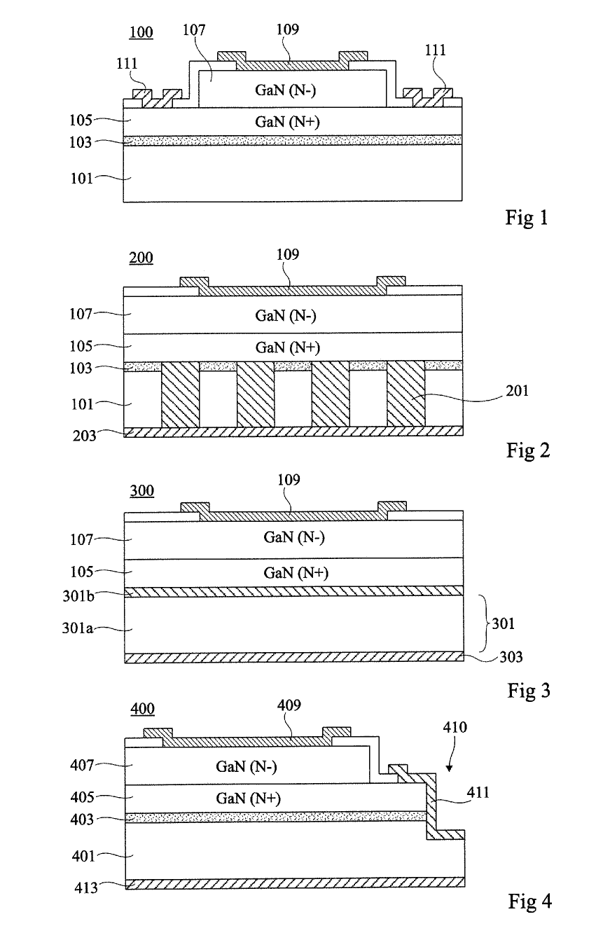

FIGS. 1 and 2 show two examples of GaN Schottky diodes. To form such diodes, it is started from a crystalline substrate 101, for example, made of sapphire (Al2O3), silicon, or silicon carbide. To obtain a lattice (mesh) matching with GaN, one forms, on the upper surface of a substrate 101, an intermediate buffer layer 103, for example, made of silicon nitride, aluminum nitride, or GaN. On the upper surface of buffer layer 103, a heavily-doped N-type GaN layer 105 (N+), followed by a lightly-doped N-type GaN layer 107 (N−), is grown by epitaxy. An electrode 109, for example, made of tungsten, titanium-tungsten, titanium nitride, nickel, gold, nickel-gold, platinum, platinum-gold, platinum-nickel, etc., is then deposited on the upper surface of lightly-doped GaN layer 107, to obtain a Schottky contact between electrode 109 and layer 107. A problem has to do with the presence of an insulating or highly-resistive buffer layer 103 between the substrate 101 and Schottky contact 109, which prevents easily obtaining a vertical diode between the substrate 101 and Schottky contact 109.

FIG. 1 shows a Schottky diode 100 of pseudo-vertical type. In diode 100, the surface of lightly-doped N-type GaN layer 107 above heavily-doped N-type layer 105 is limited, so that a peripheral portion of the upper surface of layer 105 is exposed. An electrode 111 is formed on the exposed portion of the upper surface of heavily-doped GaN layer 105, to obtain an ohmic contact between the electrode 111 and layer 105. To obtain a GaN layer 107 of limited extension as compared with layer 105, a selective epitaxy may, for example, be performed above an unmasked portion of the layer 105, or the layer 107 may be etched after its forming.

A disadvantage may be that such a diode raises issues in terms of bulk and assembly complexity. In particular, the presence of cathode electrode 111 on the upper surface side of the diode increases the total surface area of the diode. Further, the assembly of such a diode in an external device is more complex and/or expensive due to the fact that two distinct contacts (anode and cathode) are formed on a same surface (upper surface) of the diode.

FIG. 2 shows a Schottky diode 200 where, after manufacturing of the stack of layers 103, 105, and 107 on the upper surface of substrate 101, openings have been formed from the lower surface of substrate 101, these openings crossing the entire substrate 101 and buffer layer 103 to emerge into the heavily-doped N-type GaN layer 105. The openings are filled with a conductive material 201. A metallization 203 coating the lower surface of substrate 101 is in contact with the conductive material 201 and forms a cathode electrode of the diode 200.

This type of structure may have the disadvantage of having a particularly complex manufacturing method. In particular, the forming of openings from the lower surface of substrate 101 is relatively constraining. Further, the making of contacts on the lower surface of GaN layer 105 (nitrogen side) may be difficult.

FIG. 3 illustrates another embodiment of a GaN Schottky diode 300. To form such a diode, it is started, as in the examples of FIGS. 1 and 2, from a substrate 101 (not shown in FIG. 3) having an intermediate buffer layer 103 (not shown in FIG. 3) formed thereon. A difference with the examples of FIGS. 1 and 2 is that, in the example of FIG. 3, an epitaxial growth on the buffer layer 103, first of lightly-doped N-type GaN layer 107 (N−), and then of heavily-doped N-type GaN layer 105 (N+), is performed. The order of the forming of the layers 105 and 107 is thus reversed with respect to the examples of FIGS. 1 and 2. The structure thus obtained is then assembled with a second strongly-conductive substrate 301 on the side of heavily-doped N-type layer 105.

In the illustrated example, the substrate 301 comprises a heavily-doped silicon support 301a, coated with a metal layer 301b on the side of its surface in contact with the layer 105. The substrate 101 and buffer layer 103 are then removed, after which a Schottky contact 109 is formed on the surface of lightly-doped N-type layer 107 opposite to substrate 301. A metallization 303, coating the surface of the substrate 301 opposite to the layer 105, forms a cathode electrode of diode 300. A disadvantage may be that the forming of this type of structure is relatively complex due to the need to assemble a plurality of substrates.

FIG. 4 illustrates an embodiment of a GaN Schottky diode 400. To form such a diode, it is started from a conductor or semiconductor substrate 401. As a non-limiting example, the substrate 401 may be a heavily-doped silicon substrate, for example, a silicon substrate having a doping level greater than 10¹⁹ atoms/cm³ and preferably greater than 10²⁰ atoms/cm³. To obtain a lattice matching with GaN, one forms, on the upper surface of substrate 401, an intermediate buffer layer 403, for example, made of silicon nitride, aluminum nitride, or GaN. On the upper surface of layer 403, an N-type doped GaN layer 405 having a first doping level (N+), for example, a doping level in the range from 1*10¹⁸ atoms/cm³ to 5*10²⁰ atoms/cm³, followed by an N-type doped GaN layer 107 having a second doping level (N−) lower than the first level, for example, a doping level in the range from 1*10¹⁵ atoms/cm³ and 5*10¹⁶ atoms/cm³, is grown by epitaxy. An electrode 409, for example, made of tungsten, titanium-tungsten, titanium nitride, nickel, gold, nickel-gold, platinum, platinum-gold, platinum-nickel, etc., is then deposited on the upper surface of more lightly doped GaN layer 407, to obtain a Schottky contact between electrode 409 and layer 407.

According to an aspect, the diode 400 comprises a metallization 411 connecting the upper surface of GaN layer 405 to substrate 401. The metallization 411 is located in an opening 410 extending, in the stack formed by layers 403, 405, and 407, from the upper surface of layer 407 to substrate 401. The opening 410 and metallization 411 are located in an area of stack 403-405-407, which is not coated with the Schottky contact 409. The opening 410 and metallization 411, for example, extend along a portion of or the entire periphery of the Schottky contact 409.

In this example, the opening 410 comprises an upper portion, crossing the GaN layer 407, and a lower, narrower portion crossing the GaN layer 405 and buffer layer 403 and emerging into or onto the substrate 401. Thus, a portion of the upper surface of the GaN layer 405 is accessible in a peripheral portion of opening 410 and a portion of an upper surface of the substrate 401 is accessible in a central portion of opening 410, the two surface portions being connected by metallization 411. As a non-limiting example, the metallization 411 is made of titanium-aluminum, of titanium-aluminum-nickel-gold, of titanium-aluminum-platinum-gold, of titanium-aluminum-titanium-tungsten, of aluminum, of aluminum-copper, or of aluminum-silicon-copper.

In the shown example, a metallization 413, for example, made of titanium-nickel-gold or of aluminum-nickel-gold, coats the lower surface of the substrate 401 and forms a cathode electrode of the diode 400. As a non-limiting example, the substrate 401 may have a thickness in the range from 90 to 500 μm, for example, in the order of from 150 to 250 μm, the buffer layer 403 may have a thickness in the range from 0.5 and 5 μm, the heavily-doped GaN layer 405 may have a thickness in the range from 0.5 and 5 μm, and the lightly-doped GaN layer 407 may have a thickness in the range from 1 to 10 μm.

An advantage of the diode 400 of FIG. 4 is that it has a vertical structure, which eases its assembly in a device external with respect to a pseudo-vertical diode of the type described in relation with FIG. 1. Further, the structure of FIG. 4 enables, for identical Schottky junction surface areas, a decrease in the total surface area of the diode with respect to a structure of the type described in relation with FIG. 1. Indeed, since the metallization 411 of the structure of FIG. 4 is not intended to be connected to an external device, but only to electrically connect layer 405 to substrate 401, it may, in practice, occupy a much smaller surface area than cathode metallization 411 of FIG. 1.

Further, the structure of FIG. 4 is much simpler to form than vertical structures of the type described in relation with FIGS. 2 and 3. Indeed, the forming of the structure of FIG. 4 does not comprise etching the substrate from the rear surface (lower surface) and does not comprise assembling a plurality of substrates.

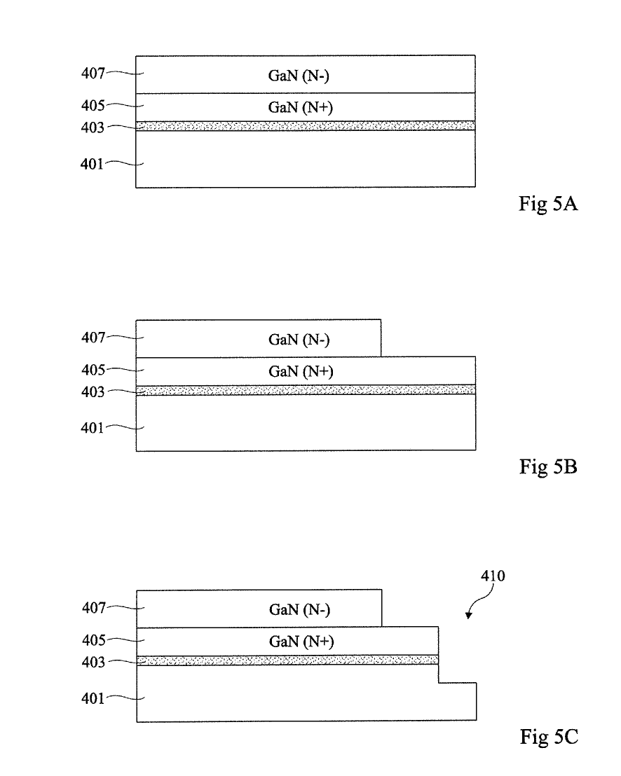

FIGS. 5A to 5C illustrate steps of an example of a method of forming a Schottky diode of the type described in relation with FIG. 4. More specifically, FIGS. 5A to 5C show an example of a method enabling to form an opening 410 of the structure of FIG. 4, intended to receive metallization 411 connecting the upper surface of GaN layer 405 to an upper surface of the substrate 401.

FIG. 5A shows an initial structure comprising a substrate 401 and, substantially coating the entire surface of substrate 401, a stack formed by a buffer layer 403, a heavily-doped GaN layer 405, and a lightly-doped GaN layer 407. FIG. 5B shows a first etch step during which the entire thickness of GaN layer 407 is removed from a peripheral portion of the stack, to form the upper portion of the opening 410.

FIG. 5C shows a second etch step during which the entire thickness of GaN layer 405 and the entire thickness of buffer layer 403 are removed from a portion of the stack located opposite to a central portion of the opening formed at the previous step, to form the lower portion of the opening 410. In the shown example, during the second etch step, the opening 410 is continued all the way to an intermediate level of the substrate 401. In this example, during the etch steps of FIGS. 5B and 5C, two etch masks having openings of different dimensions are used, to obtain an opening 410 having a lower portion narrower than its upper portion, where a portion of the upper surface of GaN layer 405 and portion of an upper surface of substrate 401 are made accessible to be subsequently connected by the metallization 411. The other steps in the process to achieve the structure of FIG. 4 are not shown, particularly the steps of forming metallizations 409, 411, and 413. The implementation of these steps is within the abilities of those skilled in the art.

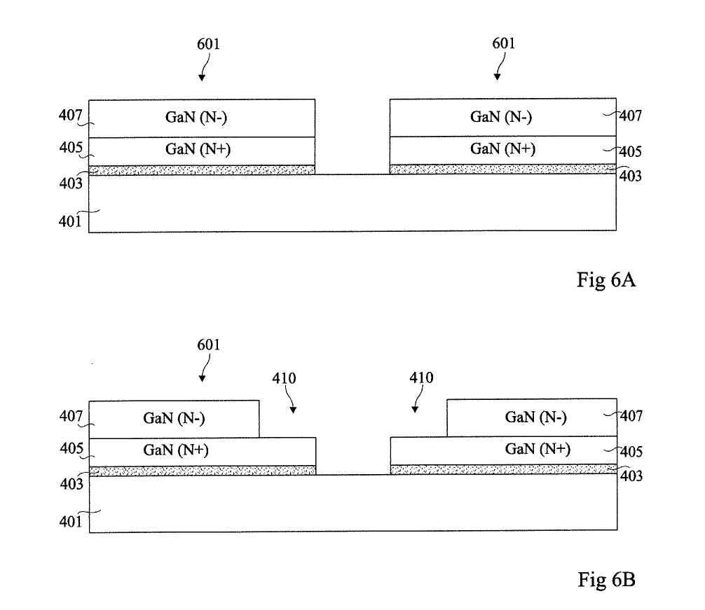

FIGS. 6A and 6B are illustrating steps of another example of a method of forming a Schottky diode of the type described in relation with FIG. 4. More specifically, FIGS. 6A and 6B show an example of a method providing the opening 410 of the structure of FIG. 4, intended to receive metallization 411 connecting the upper surface of GaN layer 405 to an upper surface of substrate 401.

FIG. 6A shows an initial structure comprising the substrate 401 and, on the upper surface of the substrate 401, a plurality of islands or blocks 601 (two islands in the shown example), each comprising a stack of a buffer layer 403, of a heavily-doped N-type GaN layer 405, and of a lightly-doped N-type GaN layer 407. To obtain such a structure, the layers 403, 405, and 407, are deposited locally. As an example, during the growth of layers 403, 405, and 407, a mask may be provided to prevent the growth of these layers in the separation areas between islands 601. From such an initial structure, it may, for example, be provided to form, inside and on top of each island 601, a Schottky diode of the type described in relation with FIG. 4.

FIG. 6B shows an etch step during which the entire thickness of the GaN layer 407 is removed from a peripheral portion of each island 601, to form the upper portion of opening 410. The lower portion of the opening 410, crossing GaN layer 405 and emerging onto the upper surface of substrate 401, is formed by the separation region between the islands 601. The other steps enabling to achieve the structure of FIG. 4, particularly the steps of forming metallizations 409, 411, and 413, have not been detailed, the implementation of these steps being within the abilities of those skilled in the art.

Specific embodiments have been described. Various alterations, modifications, and improvements will readily occur to those skilled in the art. In particular, the described embodiments are not limited to the above-mentioned specific examples of numerical values, particularly to the examples of layer thicknesses and of doping levels. Further, the described embodiments are not limited to the above-mentioned specific examples of materials, particularly to form metallizations 409, 411, and 413, substrate 401, and buffer layer 403. Further, the described embodiments are not limited to the above-mentioned examples of methods of manufacturing a diode of the type described in relation with FIG. 4.

Such alterations, modifications, and improvements are intended to be part of this disclosure, and are intended to be within the spirit and the scope of the present disclosure. Accordingly, the foregoing description is by way of example only and is not intended to be limiting. The present disclosure is limited only as defined in the following claims and the equivalents thereto.

1-7. (canceled)

8. A Schottky diode comprising:
a semiconductor substrate having first and second opposing surfaces;
a buffer layer over the first surface of said semiconductor substrate;
a first doped GaN layer over said buffer layer and having first and second opposing surfaces, the second surface of said first doped gallium nitride (GaN) layer being adjacent said buffer layer;
a second doped GaN layer over the second surface of said first doped GaN layer and having a dopant concentration level less than a dopant concentration level of said first doped GaN layer;
said buffer layer, said first doped GaN layer, and said second doped GaN layer defining a peripheral opening;
a Schottky contact over said second doped GaN layer and spaced apart from the peripheral opening;
a first metallization layer being coupled to said semiconductor substrate and to the first surface of said first doped GaN layer and being in the peripheral opening; and
a second metallization layer over the second surface of said semiconductor substrate.

9. The Schottky diode of claim 8 wherein the peripheral opening comprises:
a first portion extending through said second doped GaN layer and to the first surface of said first doped GaN layer; and
a second portion extending through said first and second doped GaN layers and said buffer layer, and extending into said semiconductor substrate.

10. The Schottky diode of claim 8 wherein the peripheral opening extends up to the first surface of said semiconductor substrate.

11. The Schottky diode of claim 8 wherein the peripheral opening extends to an intermediate level of said semiconductor substrate.

12. The Schottky diode of claim 8 wherein said semiconductor substrate comprises silicon.

13. The Schottky diode of claim 8 wherein said first metallization layer is configured to not be coupled to an external component.

14. A Schottky diode comprising:
a semiconductor substrate having first and second opposing surfaces;
a buffer layer over the first surface of said semiconductor substrate;
a first doped GaN layer over said buffer layer and having first and second opposing surfaces, the second surface of said first doped gallium nitride (GaN) layer being adjacent said buffer layer;
a second doped GaN layer over the second surface of said first doped GaN layer and having a dopant concentration level less than a dopant concentration level of said first doped GaN layer;
said buffer layer, said first doped GaN layer, and said second doped GaN layer defining a peripheral opening;
a Schottky contact over said second doped GaN layer and spaced apart from the peripheral opening;
a first electrically conductive layer being coupled to said semiconductor substrate and to the first surface of said first doped GaN layer and being in the peripheral opening, said first electrically conductive layer extending laterally across said first doped GaN layer and said semiconductor substrate; and
a second electrically conductive layer over the second surface of said semiconductor substrate.

15. The Schottky diode of claim 14 wherein the peripheral opening comprises:
a first portion extending through said second doped GaN layer and to the first surface of said first doped GaN layer; and
a second portion extending through said first and second doped GaN layers and said buffer layer, and extending into said semiconductor substrate.

16. The Schottky diode of claim 14 wherein the peripheral opening extends up to the first surface of said semiconductor substrate.

17. The Schottky diode of claim 14 wherein the peripheral opening extends to an intermediate level of said semiconductor substrate.

18. A method for making a Schottky diode comprising:
providing a semiconductor substrate having first and second opposing surfaces;
forming a buffer layer over the first surface of the semiconductor substrate;
forming a first doped GaN layer over the buffer layer and having first and second opposing surfaces, the second surface of the first doped gallium nitride (GaN) layer being adjacent the buffer layer;
forming a second doped GaN layer over the second surface of the first doped GaN layer and having a dopant concentration level less than a dopant concentration level of the first doped GaN layer;
the buffer layer, the first doped GaN layer, and the second doped GaN layer defining a peripheral opening;
forming a Schottky contact over the second doped GaN layer and spaced apart from the peripheral opening;
forming a first metallization layer being coupled to the semiconductor substrate and to the first surface of the first doped GaN layer and being in the peripheral opening; and
forming a second metallization layer over the second surface of the semiconductor substrate.

19. The method of claim 18 wherein the peripheral opening comprises:
a first portion extending through the second doped GaN layer and to the first surface of the first doped GaN layer; and
a second portion extending through the first and second doped GaN layers and the buffer layer, and extending into the semiconductor substrate.

20. The method of claim 18 wherein the peripheral opening extends up to the first surface of the semiconductor substrate.

21. The method of claim 18 wherein the peripheral opening extends to an intermediate level of the semiconductor substrate.

22. The method of claim 18 wherein the semiconductor substrate comprises silicon.

23. The method of claim 18 wherein the first metallization layer is not coupled to an external component.
